(19) United States
(12) Patent Application Publication
(10) Pub. No.: US 2025/0218743 A1
(43) Pub. Date: Jul. 3, 2025

(54) SUBSTRATE PROCESSING APPARATUS

(71) Applicant: SEMES CO., LTD., Cheonan-si (KR)

(72) Inventors: In Ho KIM, Cheonan-si (KR); Hyoung Kyu SON, Cheonan-si (KR)

(73) Assignee: SEMES CO., LTD., Cheonan-si (KR)

(21) Appl. No.: 19/004,243

(22) Filed: Dec. 28, 2024

(30) Foreign Application Priority Data
Dec. 28, 2023 (KR) 10-2023-0193986

(51) Int. Cl. H01J 37/32; H01L 21/67

(52) U.S. Cl. CPC H01J 37/32669; H01J 37/32082; H01J 37/32449; H01J 37/32935; H01J 2237/334; H01L 21/67017

(57) ABSTRACT

Disclosed is a substrate processing apparatus including chamber having defined therein a processing space for a processing of a substrate, a substrate support unit disposed in the chamber, a gas supply unit configured to supply gas to the interior of the chamber, a plasma generation unit including a high-frequency power supply configured to generate plasma in the processing space, an electromagnet unit configured to generate a magnetic field in the processing space, and a controller. The electromagnet unit includes a coil module and a ferrofluid reservoir disposed adjacent to the coil module. The substrate processing apparatus suppresses heat generation in the coil module and precisely controls a magnetic field.

### CROSS-REFERENCE TO THE RELATED APPLICATION

The present application claims priority to and the benefit of Korean Patent Application No. 10-2023-0193986,filed on Dec. 28, 2023, in the Korean Intellectual Property Office, the entire disclosure of which is incorporated herein by reference.

### BACKGROUND

### 1. Field

The present disclosure relates to a substrate processing apparatus configured to process a substrate using plasma.

### 2. Description of the Related Art

Substrate processing apparatuses using plasma are widely used to manufacture semiconductor devices. Plasma is generally used for a deposition process for forming a predetermined film on a substrate such as a semiconductor wafer, an etching process for forming a predetermined pattern on the film formed on the substrate, etc.

In a process of processing a substrate using plasma, uniform process performance is required for each area of a wafer. To this end, not only the ability to generate uniform plasma in a processing space in a chamber, but also the ability to precisely control the density of plasma at each position is required. To this end, technology for controlling the density distribution of plasma in a chamber using an electromagnet is known.

For in the example, case of a conventional capacitively coupled plasma (CCP) etching system, there are differences not only in etch rate but also in the angle of incidence of ions incident on the surface of a wafer between the center of the wafer and the edge of the wafer. If the angle of incidence of ions incident on the edge of the wafer deviates from the vertical, it is difficult to obtain a desired pattern shape. In order to solve this problem, an electromagnet is placed on the chamber, and current is supplied to a coil of the electromagnet to generate a magnetic field, thereby controlling the density distribution of plasma generated in the chamber.

For example, Patent Document 1 discloses technology in which a plurality of annular electromagnets is placed on a chamber in order to control a magnetic field in the chamber. The plurality of annular electromagnets has different radii and is disposed so as to be spaced apart from each other in a radial direction. The density distribution of plasma in the chamber may be controlled by adjusting the current flowing through a coil of each electromagnet.

However, in this structure, if the current flowing through the coil is increased in order to obtain a desired magnetic field, heat generation in the coil is increased. For example, if current of about 10 A is supplied to the coil in order to generate a magnetic field required for a process, the temperature of the electromagnet rises to about 150° C. or higher, which is the cause of the need for a separate cooling structure.

If a magnetic substance, such as iron or ferrite, is placed adjacent to the electromagnet, magnetic resistance is reduced. Thus, even if relatively low current is supplied to the coil, a magnetic field having a desired level may be formed. However, the magnetic substance is magnetized due to the magnetic field formed by the electromagnet, and affects plasma distribution in a subsequent process. That is, due to magnetization of the magnetic substance, wafers that are sequentially introduced into the chamber to be processed undergo processing under different magnetic field distributions, thus making it difficult to perform uniform processing on the wafers. In order to solve this problem, the magnetic substance needs to be demagnetized whenever the wafers are processed, which greatly deteriorates processing efficiency.

In addition, the method of controlling the density distribution of plasma in the chamber by controlling current flowing through the coil of the electromagnet has problems in that precise control is difficult to achieve and it is difficult to independently control heat generation in the coil and the density distribution of plasma.

Therefore, there is a demand for technology capable of obtaining a magnetic field having a desired magnitude while suppressing heat generation in a coil and capable of more precisely controlling the magnetic field without the necessity of demagnetization.

### RELATED ART DOCUMENT

### Patent Document

(Patent Document 1) KR 10-2434088 B1

### SUMMARY

It is an object of the present disclosure to provide a substrate processing apparatus including an electromagnet, specifically, a substrate processing apparatus capable of forming a magnetic field having a desired magnitude while suppressing heat generation in a coil included in the electromagnet.

In addition, it is another object of the present disclosure to provide a substrate processing apparatus capable of precisely controlling a magnetic field.

In addition, it is a further object of the present disclosure to provide a substrate processing apparatus capable of improving substrate processing efficiency without the necessity of demagnetization.

In accordance with an aspect of the present disclosure, the above and other objects can be accomplished by the provision of a substrate processing apparatus including a chamber having defined therein a processing space for processing of a substrate, a substrate support unit disposed in the chamber, a gas supply unit configured to supply gas to the interior of the chamber, a plasma generation unit including a high-frequency power supply configured to generate plasma in the processing space, an electromagnet unit configured to generate a magnetic field in the processing space, and a controller, wherein the electromagnet unit includes a coil module and a ferrofluid reservoir disposed adjacent to the coil module.

In one embodiment of the present disclosure, the coil module may include a plurality of unit coils, and the ferrofluid reservoir may be disposed between the plurality of unit coils.

In one embodiment of the present disclosure, the ferrofluid reservoir may include plurality of unit ferrofluid reservoirs, and each of the plurality of unit ferrofluid reservoirs may be formed in an annular shape or a cylindrical shape.

In one embodiment of the present disclosure, the plurality of unit coils may include annular coils having different diameters and disposed concentrically with each other, and at least one of the plurality of unit ferrofluid reservoirs may be disposed between every two adjacent ones of the plurality of unit coils.

The substrate processing apparatus according to the embodiment of the present disclosure may further include a ferrofluid source and a ferrofluid pipe configured to supply ferrofluid from the ferrofluid source to the ferrofluid reservoir.

In one embodiment of the present disclosure, the ferrofluid reservoir may include a plurality of unit ferrofluid reservoirs, and the ferrofluid source may be configured to supply the ferrofluid to the plurality of unit ferrofluid reservoirs.

In one embodiment of the present disclosure, the ferrofluid reservoir may include a plurality of unit ferrofluid reservoirs. The ferrofluid source may be provided in plural, and each of the plurality of ferrofluid sources may be configured to supply the ferrofluid to at least one of the plurality of unit ferrofluid reservoirs.

In one embodiment of the present disclosure, the plurality of ferrofluid sources may supply different types of ferrofluids.

In one embodiment of the present disclosure, the ferrofluid reservoir may include a plurality of unit ferrofluid reservoirs, and the plurality of unit ferrofluid reservoirs may communicate with each other through a connection pipe.

In one embodiment of the present disclosure, the coil module may include a first coil and a second coil, and a plurality of f unit ferrofluid reservoirs may be disposed between the first coil and the second coil. In this case, the plurality of unit ferrofluid reservoirs may be disposed so as to be stacked in a vertical direction or may be disposed so as to be separate from each other in a peripheral direction.

The substrate processing apparatus according to the embodiment of the present disclosure may further include a recovery pipe configured to receive ferrofluid recovered from the ferrofluid reservoir, a ferrofluid tank configured to store the recovered ferrofluid, and a supplement pipe configured to transfer the ferrofluid from the ferrofluid tank to the ferrofluid source.

In accordance with another aspect of the present disclosure, there is provided a substrate processing apparatus including a chamber having defined therein a processing space for processing of a substrate, a substrate support unit disposed in the chamber, a gas supply unit configured to supply gas to the interior of the chamber, a plasma generation unit including a high-frequency power supply configured to generate plasma in the processing space, an electromagnet unit configured to generate a magnetic field in the processing space, and a controller, wherein the electromagnet unit includes a coil module and first and second ferrofluid reservoirs disposed adjacent to the coil module, and the substrate processing apparatus further includes a first ferrofluid source configured to selectively supply ferrofluid to the first ferrofluid reservoir and the second ferrofluid reservoir, a first pipe connecting the first ferrofluid source to the first ferrofluid reservoir, a first branch pipe branching from the first pipe to be connected to the second ferrofluid reservoir, and a first ferrofluid flow control device configured to control a ferrofluid supply path so that the ferrofluid is supplied to the first ferrofluid reservoir through the first pipe or is supplied to the second ferrofluid reservoir through the first branch pipe.

The substrate processing apparatus according to the embodiment of the present disclosure may further include a second ferrofluid source configured to selectively supply ferrofluid to the first ferrofluid reservoir and the second ferrofluid reservoir, a second pipe connecting the second ferrofluid source to the second ferrofluid reservoir, a second branch pipe branching from the second pipe to be connected to the first ferrofluid reservoir, and a second ferrofluid flow a control device configured to control ferrofluid supply path so that the ferrofluid is supplied to the second ferrofluid reservoir through the second pipe or is supplied to the first ferrofluid reservoir through the second branch pipe.

In one embodiment of the present disclosure, the first ferrofluid source may supply first ferrofluid, the second ferrofluid source may supply second ferrofluid, and the first ferrofluid and the second ferrofluid may be different types of ferrofluids.

In one embodiment of the present disclosure, one of the first ferrofluid and the second ferrofluid may be supplied to the first ferrofluid reservoir and the second ferrofluid reservoir by the first ferrofluid flow control device and the second ferrofluid flow control device.

In accordance with a further aspect of the present disclosure, there is provided a substrate processing apparatus including a chamber having defined therein a processing space for processing of a substrate, a substrate support unit disposed in the chamber, a gas supply unit configured to supply gas to the interior of the chamber, a plasma generation unit including a high-frequency power supply configured to generate plasma in the processing space, an electromagnet unit configured to generate a magnetic field in the processing space, and a controller, wherein the electromagnet unit includes a coil module and a ferrofluid reservoir disposed adjacent to the coil module, and the controller performs control to implement a first process of introducing the substrate into the chamber and placing the substrate onto the substrate support unit, a second process of supplying ferrofluid to the ferrofluid reservoir, a third process of applying current to the coil module and controlling the plasma generation unit to generate plasma in the processing space so that the substrate is plasma-processed, and a fourth process of recovering the ferrofluid from the ferrofluid reservoir when the substrate is completely plasma-processed.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 is a cross-sectional view of a substrate processing apparatus according to an embodiment of the present disclosure;

FIGS. 2 and 3 are views for explaining the configuration of an electromagnet unit according to an embodiment of the present disclosure;

FIG. 4 is a view for explaining the effect of a ferrofluid reservoir;

FIGS. 5 to 8 are views for explaining arrangement structures of the ferrofluid reservoir according to embodiments of the present disclosure;

FIGS. 9A to 9D are views for explaining ferrofluid supply structures according to embodiments of the present disclosure;

FIG. 10 is a view for explaining a ferrofluid discharge structure according to an embodiment of the present disclosure; and

FIG. 11 is a flowchart of a substrate processing method according to an embodiment of the present disclosure.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

Parts irrelevant to description of the present disclosure will be omitted to clearly describe the present disclosure, and the same or similar constituent elements will be denoted by the same reference numerals throughout the specification.

In addition, constituent elements having the same configurations in several embodiments will be assigned with the same reference numerals and described only in the representative embodiment, and only constituent elements different from those of the representative embodiment will be described in the other embodiments.

Throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

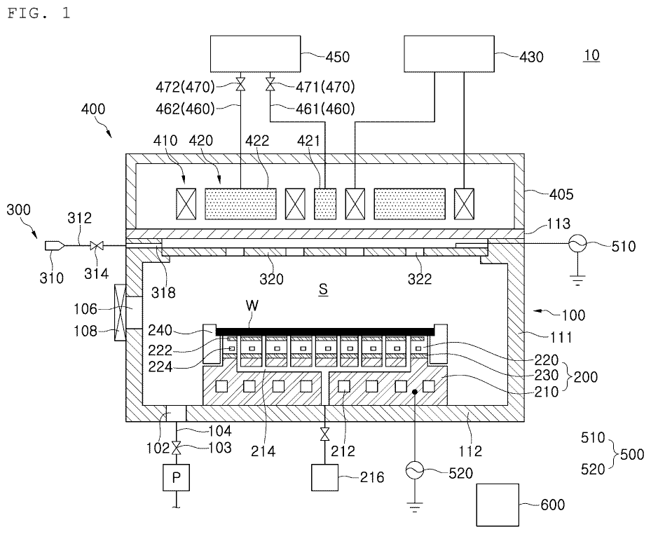

FIG. 1 is a cross-sectional view of a substrate processing apparatus according to an embodiment of the present disclosure.

Referring to FIG. 1, a substrate processing apparatus 10 according to an embodiment of the present disclosure includes a chamber 100, a substrate support unit 200, a gas supply unit 300, an electromagnet unit 400, a plasma generation unit 500, and a controller 600.

The chamber 100 has defined therein a processing space s in which a substrate-processing process is performed. The processing space s is defined in the chamber 100 by a chamber sidewall 111, a chamber bottom 112, and a chamber cover 113. The chamber 100 may be made of metal such as aluminum. The substrate-processing process may be a process of plasma-processing a substrate W. For example, the substrate-processing process may be a plasma etching process. The substrate-processing process may be performed in a reduced-pressure atmosphere. To this end, the chamber 100 may include an exhaust port 102 formed therein. The exhaust port 102 may be formed in the chamber bottom 112. A vacuum pump P is connected to the exhaust port 102 via an exhaust line 104 and an exhaust valve 103. The pressure in the processing space s in the chamber 100 may be adjusted to a predetermined pressure by operating the vacuum pump P and controlling the exhaust valve 103.

An opening 106 may be formed in the sidewall of the chamber 100. The opening 106 functions as a passage through which the substrate W is introduced into and removed from the chamber 100. An opening/closing door 108 is mounted in the opening 106. The opening/closing door 108 functions to open and close the opening 106 in the chamber 100. In the closed state, the opening/closing door 108 hermetically seals the processing space s in the chamber 100. In the open state, the opening/closing door 108 allows the substrate W to be transferred from a transfer space outside the chamber 100 to the processing space s or from the processing space s to the transfer space outside the chamber 100. The opening/closing door 108 may be a gate valve.

A substrate support unit 200 configured to support the substrate W is provided in the chamber 100. The substrate support unit 200 may include an electrostatic chuck 220 configured to attract and fix the substrate W thereto and a base plate 210 configured to support the electrostatic chuck 220. The electrostatic chuck 220 and the base plate 210 may be bonded to each other by means of a bonding layer 230, and the bonding layer 230 may be made of silicone or the like.

The electrostatic chuck 220 may be implemented as a dielectric plate made of alumina or the like, and may be provided therein with a chuck electrode 222 to generate electrostatic force. If voltage is applied to the chuck electrode 222 from a power supply (not shown), electrostatic force is generated, whereby the substrate W is attracted and fixed to the electrostatic chuck 220. The electrostatic chuck 220 may be provided with a heater 224 to adjust the temperature of the substrate W.

The base plate 210 may be located under the electrostatic chuck 220, and may be made of metal such as aluminum. The base plate 210 may have formed therein a refrigerant flow path 212 through which a cooling fluid flows, thereby functioning as a cooling device to cool the substrate W. The refrigerant flow path 212 may be provided as a circulation passage through which the cooling fluid circulates.

In addition, the substrate support unit 200 may have a heat transfer gas flow path 214 formed therein to provide a heat transfer gas to a lower surface of the substrate W from a heat transfer gas source 216. The heat transfer gas may facilitate heat transfer between the substrate W and the base plate 210, thereby promoting cooling of the substrate W. Helium (He) may be used as the heat transfer gas.

The substrate support unit 200 may include a ring member 240 to surround the periphery of the electrostatic chuck 220. The ring member 240 may have a stepped portion formed on an upper side thereof to support the outer circumferential surface of the substrate W. The ring member 240 may be made of a ceramic material, and may be a focus ring.

The gas supply unit 300 supplies gas required to process the substrate W to the chamber 100. The gas supply unit 300 may include a gas source 310, a gas supply line 312, a gas supply valve 314, a gas spray nozzle 318, and a showerhead 320. The gas supply line 312 connects the gas source 310 to the gas spray nozzle 318. A gas supply valve 314 is mounted on the gas supply line 312 in order to open and close the passage thereof or to regulate the flow rate of fluid flowing through the passage. Gas sprayed from the gas spray nozzle 318 is supplied to a space between the chamber cover 113 and the showerhead 320, and is then supplied to the processing space s through gas spray holes 322 formed in the showerhead 320.

Although one gas source 310, one gas supply line 312, and one gas supply valve 314 are illustrated in FIG. 1, the gas source 310 of the present disclosure may include plurality of gas sources to supply a plurality of gases to the chamber 100 and a plurality of gas supply valves to independently control the supply of the respective gases. The plurality of gases may include a process gas used for a process of processing the substrate W, e.g., an etching gas, and may include an inert purge gas.

The plasma generation unit 500 may include high-frequency power supplies 510 and 520 to supply high-frequency power, thereby generating plasma in the processing space s. The high-frequency power supplies 510 and 520 may provide high-frequency power in the range of several hundred kHz to several hundred MHz.

The high-frequency power supply 510 may supply high-frequency power to an upper electrode, and the showerhead 320 may function as the upper electrode. The high-frequency power supply 520 may supply high-frequency power to a lower electrode, and the substrate support unit 200 may function as the lower electrode. Although the high-frequency power supplies 510 and 520 are illustrated in FIG. 1 as being connected to the upper electrode and the lower electrode, respectively, it should be understood that this configuration is merely exemplary. In order to generate plasma in the processing space s, the upper electrode may be grounded, and high-frequency power may be applied only to the lower electrode from the lower power supply 520. Alternatively, high-frequency power may be applied to the upper electrode from the upper power supply 510, and the lower electrode may be grounded. Alternatively, high-frequency power may be applied both to the upper electrode and to the lower electrode. A plurality of high-frequency power supplies having different frequencies may be used as the lower power supply 520.

The high-frequency power supplies 510 and 520 may apply power in a continuous mode or a pulse mode.

The electromagnet unit 400 is disposed on the chamber 100, and is configured to generate a magnetic field in the processing space s. The electromagnet unit 400 includes a housing 405, a coil module 410, a ferrofluid reservoir 420, and an electromagnet excitation power supply 430. When current is supplied to the coil module 410 from the electromagnet excitation power supply 430, a magnetic field is generated in the processing space s as the current flows through the coil. Because the magnetic field generated in the processing space s is varied by controlling the current supplied to the coil module, it is possible to control the density distribution of plasma generated in the processing space s. The electromagnet excitation power supply 430 may be a direct current (DC) power supply that supplies direct current to the coil module.

The controller 600 may control overall operation of the substrate processing apparatus 10. For example, the controller 600 may control operation of the gas supply unit 300, the plasma generation unit 500, and the electromagnet unit 400 so that plasma processing is performed on the substrate W. For example, the controller 600 may control the gas supply unit 300 to supply a predetermined etching gas to the processing space s, and may control the high-frequency power supplies 510 and 520 to generate plasma in the processing space s, thereby etching the substrate W. In this case, the controller 600 may control the electromagnet unit 400 to generate a magnetic field in the processing space s, thereby appropriately controlling the density distribution of the plasma. Accordingly, it is possible to achieve uniform etching over the entire area of the substrate W.

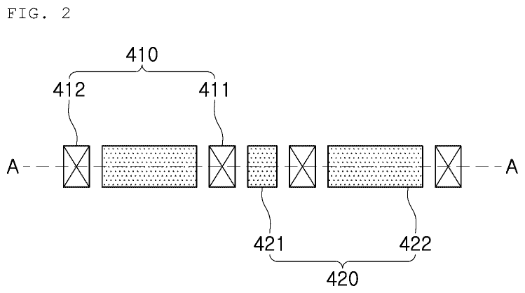

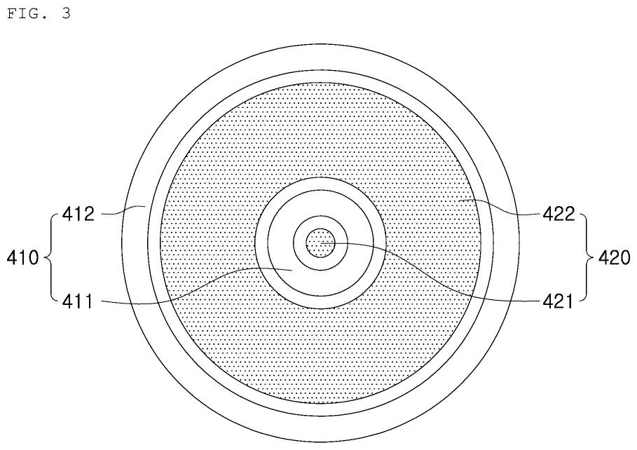

FIGS. 2 and 3 are views for explaining the configuration of the electromagnet unit 400 according to an embodiment of the present disclosure. FIG. 2 is a cross-sectional view for explaining the arrangement structure of the coil module 410 and the ferrofluid reservoir 420, and FIG. 3 is a top view of the cross-section taken along line A-A in FIG. 2.

Referring to FIGS. 2 and 3, the electromagnet unit 400 according to an embodiment of the present disclosure includes the coil module 410. The coil module 410 may include a plurality of unit coils 411 and 412. The unit coils 411 and 412 may be annular coils having different diameters, and may be disposed concentrically with each other, as shown in FIG. 3.

For example, the coil module 410 may include a first coil 411 formed in an annular shape and a second coil 412 formed in an annular shape having a larger diameter than the first coil 411 and disposed concentrically with the first coil 411. The outer diameter of the first coil 411 may be smaller than the inner diameter of the second coil 412. When viewed from above, the first coil 411 may be disposed inside the inner peripheral surface of the second coil 412. Although the coil module 410 is illustrated in FIGS. 2 and 3 as including two unit coils, the disclosure is not limited thereto. The coil module 410 may include more than two unit coils.

Each of the unit coils 411 and 412 may be provided in a form in which a coil is wound around a bobbin. The bobbin may be formed in an annular shape, and may be made of a material allowing a magnetic field to pass therethrough. For example, the bobbin may be made of aluminum.

The ferrofluid reservoir 420 may be disposed between the unit coils 411 and 412. The ferrofluid reservoir 420 may include a plurality of unit ferrofluid reservoirs 421 and 422. The unit ferrofluid reservoirs 421 and 422 may be formed in annular shapes different diameters or cylindrical shapes. As shown in FIG. 3, the unit ferrofluid reservoirs 421 and 422 may be disposed concentrically with each other. For example, the ferrofluid reservoir 420 may include a first ferrofluid reservoir 421 formed in a cylindrical shape and spaced apart from the inner wall of the first coil 411 having an annular shape and a second ferrofluid reservoir 422 formed in an annular shape and disposed between the first coil 411 and the second coil 412 while being concentric with the first ferrofluid reservoir 421. Although the ferrofluid reservoir 420 is illustrated in FIGS. 2 and 3 as including two unit ferrofluid reservoirs, the disclosure is not limited thereto. The ferrofluid reservoir 420 may include more than two unit ferrofluid reservoirs depending on the configuration of the coil module 410. That is, the ferrofluid reservoir 420 may include unit ferrofluid reservoirs, the number of which is identical to or greater than the number of unit coils constituting the coil module 410.

The ferrofluid reservoir 420 has a storage space defined therein so as to be filled with ferrofluid. Referring to FIG. 1 together, the ferrofluid reservoir 420 receives ferrofluid from a ferrofluid source 450 through a ferrofluid pipe 460. The ferrofluid supplied from the ferrofluid source 450 fills the ferrofluid reservoir 420, and thus is located between the unit coils 411 and 412.

The ferrofluid pipe 460 may be connected to each of the plurality of unit ferrofluid reservoirs 421 and 422. For example, a first pipe 461 may be connected to the first ferrofluid reservoir 421, and a second pipe 462 may be connected to the second ferrofluid reservoir 422. The first pipe 461 and the second pipe 462 may be connected to the ferrofluid source 450 to supply ferrofluid to the first ferrofluid reservoir 421 and the second ferrofluid reservoir 422, respectively.

A ferrofluid flow control device 470 may be mounted on the ferrofluid pipe 460 in order to control the flow of the ferrofluid. The ferrofluid flow control device 470 may be a valve. For example, a first valve 471 may be mounted on the first pipe 461, and a second valve 472 may be mounted on the second pipe 462. The ferrofluid flow control device 470 may be opened so that the ferrofluid is supplied to the ferrofluid reservoir 420, and may be closed when the supply of the ferrofluid is completed. The ferrofluid flow control device 470 may be an on-off valve or a flow control valve.

The ferrofluid pipe 460 may be used to supply the ferrofluid from the ferrofluid source 450 to the ferrofluid reservoir 420, and may also be used to recover the ferrofluid from the ferrofluid reservoir 420 to the ferrofluid source 450. That is, the ferrofluid pipe 460 may be used for both the supply and the recovery of the ferrofluid.

In the embodiment of the present disclosure, the ferrofluid is a fluid substance in which fine magnetic powders are dispersed in a solvent. The disclosure is not limited to any specific fluid substance. The magnetic powder may be a powder of a magnetic material containing at least one element of silicon (Si), cobalt (Co), or iron (Fe). The magnetic powder may be a powder of a material having magnetic permeability of 10 to 10,000 H/m. The solvent in which the magnetic powders are dispersed is not particularly limited, as long as the solvent is a liquid substance capable of uniformly dispersing the magnetic powders. The solvent may be water or an organic solvent. When a magnetic field is present, the ferrofluid may be magnetized as the magnetic powders are oriented along the magnetic field, and when the magnetic field is removed, the magnetic powders may be randomly dispersed, and the ferrofluid may be demagnetized.

As shown in FIG. 2, the ferrofluid reservoir 420 may be formed to have a height sufficient to isolate the unit coils 411 and 412 from each other.

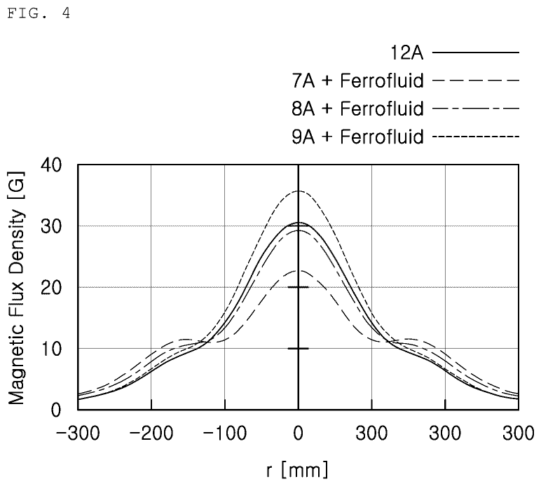

FIG. 4 is a view for explaining the effect of the ferrofluid reservoir, showing a magnetic flux density at each position. The position r is a position in the radial direction with the center of the electromagnet unit 400 defined as 0. Referring to FIG. 4, it can be seen that, in the state in which the ferrofluid supplied to the ferrofluid reservoir, a magnetic flux density having a given level is obtained with relatively small current compared to a configuration in which only a coil is provided without a ferrofluid reservoir. For example, the magnetic flux density when current of 8 A is supplied in the state in which the ferrofluid is supplied is similar to the magnetic flux density when current of 12 A is supplied without ferrofluid. Further, if the current is increased to 9 A in the state in which the ferrofluid is supplied, the magnetic flux density greatly increases compared to when current of 12 A is supplied without ferrofluid. As described above, the embodiment of the present disclosure, in which the ferrofluid reservoir is disposed between the coils and the ferrofluid is supplied to the ferrofluid reservoir, may obtain a large magnetic field with small current, and accordingly, may minimize heat generation in the coils.

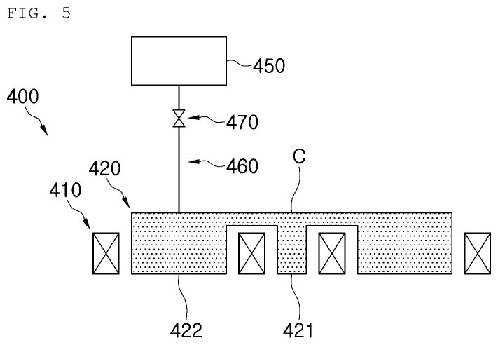

FIGS. 5 to 8 are views for explaining various arrangement structures of the ferrofluid reservoir according to embodiments of the present disclosure.

FIG. 5 shows a structure in which the unit ferrofluid reservoirs 421 and 422 are connected to each other. That is, the first ferrofluid reservoir 421 and the second ferrofluid reservoir 422 communicate with each other through a connection pipe C. In this structure, the ferrofluid source 450 and the ferrofluid reservoir 420 may be connected to each other via a single ferrofluid pipe 460. That is, the ferrofluid supplied from the ferrofluid source 450 to the ferrofluid reservoir 420 through the ferrofluid pipe 460 may fill both the first ferrofluid reservoir 421 and the second ferrofluid reservoir 422 through the connection pipe C. In addition, after the substrate-processing process is completed, the ferrofluid may be recovered to the ferrofluid source 450 through the ferrofluid pipe 460. According to the structure shown in FIG. 5, the ferrofluid pipe structure may be simplified compared to the structure in which the ferrofluid reservoir 420 is constituted by a plurality of separate unit ferrofluid reservoirs 421 and 422.

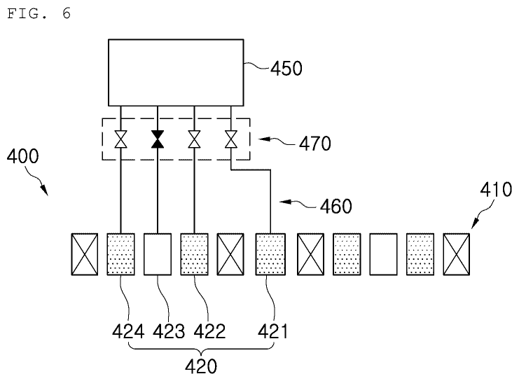

FIG. 6 shows a structure in which a larger number of unit ferrofluid reservoirs 422, 423, and 424 is disposed between the first coil 411 and the second coil 412 compared to the arrangement structure shown in FIG. 2. In this way, when a larger number of unit ferrofluid reservoirs is disposed, it is possible to more finely control the magnetic field.

For example, a second ferrofluid reservoir 422, a third ferrofluid reservoir 423, and a fourth ferrofluid reservoir 424 may be disposed between the first coil 411 and the second coil 412. The second ferrofluid reservoir 422, the third ferrofluid reservoir 423, and the fourth ferrofluid reservoir 424 may be formed in annular shapes having different diameters. The second ferrofluid reservoir 422 may be disposed between the first coil 411 and the second coil 412 while being concentric with the first ferrofluid reservoir 421 formed in a cylindrical shape, the third ferrofluid reservoir 423 may be formed in an annular shape having a larger diameter than the second ferrofluid reservoir 422 and may be disposed between the second ferrofluid reservoir 422 and the second coil 412, and the fourth ferrofluid reservoir 424 may be formed in an annular shape having a larger diameter than the third ferrofluid reservoir 423 and may be disposed between the third ferrofluid reservoir 423 and the second coil 412.

The first ferrofluid reservoir 421, the second ferrofluid reservoir 422, the third ferrofluid reservoir 423, and the fourth ferrofluid reservoir 424 may be individually connected to the ferrofluid source 450 via ferrofluid pipes 460. A ferrofluid flow control device 470 capable of independently controlling the supply of ferrofluid may be provided on each of the ferrofluid pipes 460. The ferrofluid flow control device 470 may include an on-off valve capable of opening and closing each of the ferrofluid pipes 460.

As exemplarily shown in FIG. 6, the ferrofluid may be supplied to the first ferrofluid reservoir 421, the second ferrofluid reservoir 422, and the fourth ferrofluid reservoir 424, and the ferrofluid may not be supplied to the third ferrofluid reservoir 423. That is, the ferrofluid may be selectively supplied to the plurality of unit ferrofluid reservoirs. With this arrangement structure, it is possible to finely control the magnetic field in accordance with the process.

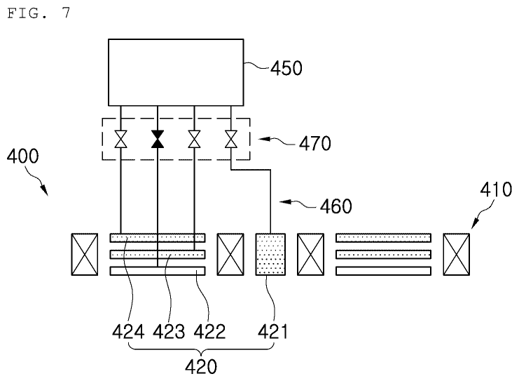

FIG. 7 shows a structure in which the second ferrofluid reservoir 422, the third ferrofluid reservoir 423, and the fourth ferrofluid reservoir 424 are stacked in a vertical direction, unlike the structure shown in FIG. 6. In detail, the second ferrofluid reservoir 422, the third ferrofluid reservoir 423, and the fourth ferrofluid reservoir 424 may be formed in annular shapes having the same diameter and may be disposed between the first coil 411 and the second coil 412. Similar to the structure shown in FIG. 6, the ferrofluid may be selectively supplied to the plurality of unit ferrofluid reservoirs. As exemplarily shown in FIG. 7, the ferrofluid may be supplied to the first ferrofluid reservoir 421, the third ferrofluid reservoir 423, and the fourth ferrofluid reservoir 424, and the ferrofluid may not be supplied to the second ferrofluid reservoir 422. According to this arrangement structure, the amount of ferrofluid supplied to the ferrofluid reservoir 420 may be controlled, so that the magnetic field may be finely controlled. In addition, as shown in FIG. 7, when the ferrofluid is not supplied to the second ferrofluid reservoir 422, which is closest to the processing space s, it is possible to obtain the same effect as when the ferrofluid reservoir 420 is raised in the height direction. Accordingly, the magnetic field may be controlled finely.

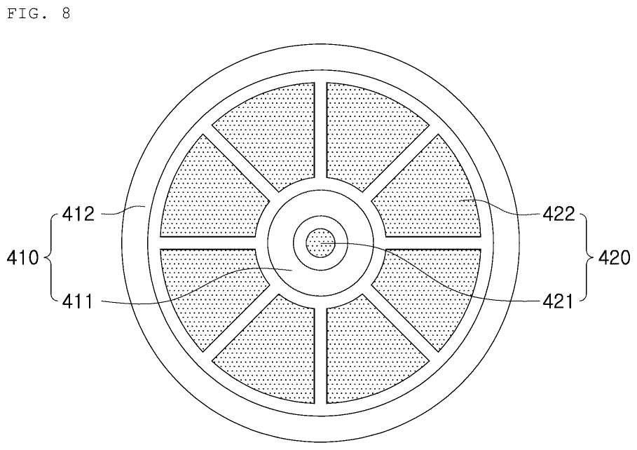

FIG. 8 shows an arrangement structure in which the ferrofluid reservoir 420 is divided into a plurality of unit ferrofluid reservoirs in the peripheral direction. The ferrofluid may be selectively supplied to the plurality of unit ferrofluid reservoirs divided in the peripheral direction. With this structure, it is possible to finely control the magnetic field in the peripheral direction.

It should be understood that the arrangement structures shown in FIGS. 5 to 8 are merely exemplary and various other arrangement structures not shown in the drawings are also included in the scope of the present disclosure. For example, the arrangement structures shown in FIGS. 5 to 8 may be combined with one another. That is, the ferrofluid reservoir 420 may be divided into a plurality of unit ferrofluid reservoirs in the radial direction, the height direction, and/or the peripheral direction, and the ferrofluid may be selectively supplied to the plurality of unit ferrofluid reservoirs.

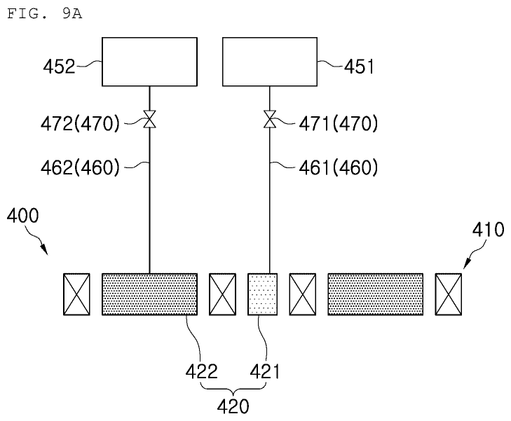

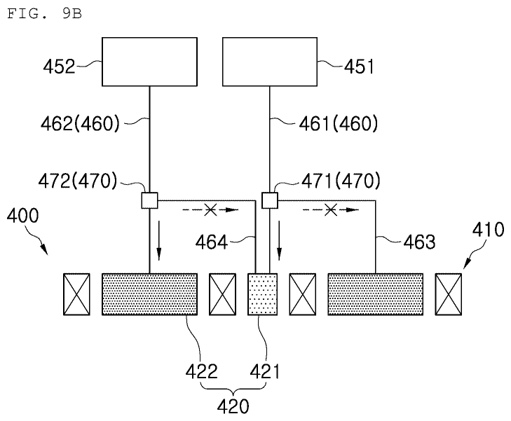

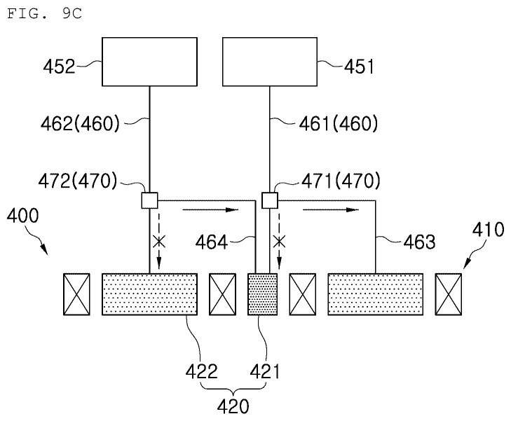

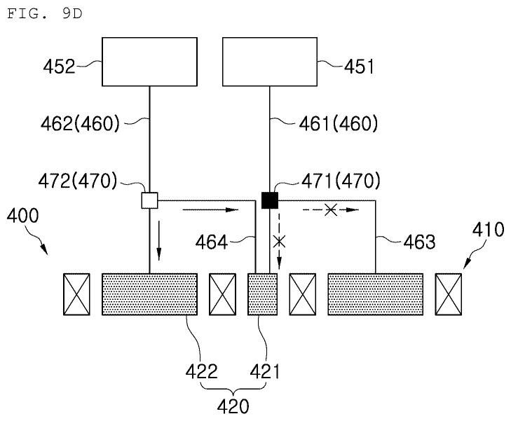

FIGS. 9A to 9D are views for explaining ferrofluid supply structures according to embodiments of the present disclosure. In the embodiments shown in FIGS. 9A to 9D, a plurality of ferrofluid sources 450 is provided. For example, the plurality of ferrofluid sources 450 may include a first ferrofluid source 451 and a second ferrofluid source 452.

Although not particularly limited, the first ferrofluid source 451 and the second ferrofluid source 452 may supply different types of ferrofluids. For example, the first ferrofluid source 451 may supply first ferrofluid, and the second ferrofluid source 452 may supply second ferrofluid. The first ferrofluid and the second ferrofluid may be ferrofluids having different magnetic permeabilities. The first ferrofluid and the second ferrofluid may include powders of different magnetic substances. Alternatively, powders of the same magnetic substance may be dispersed at different densities in the first ferrofluid and the second ferrofluid.

FIG. 9A shows a structure in which the first ferrofluid source 451 is connected to the first ferrofluid reservoir 421 via the first pipe 461 and the second ferrofluid source 452 is connected to the second ferrofluid reservoir 422 via the second pipe 462. In this supply structure, the first ferrofluid may be supplied to the first ferrofluid reservoir 421, and the second ferrofluid may be supplied to the second ferrofluid reservoir 422. In this state, a magnetic field may be formed to perform a substrate-processing process. Accordingly, it is possible to control the distribution of the magnetic field differently from the structure in which the same ferrofluid is supplied to the first and second ferrofluid reservoirs 421 and 422.

FIGS. 9B to 9D show a structure capable of selectively supplying the first ferrofluid and the second ferrofluid to the first ferrofluid reservoir 421 and the second ferrofluid reservoir 422.

A first branch pipe 463 may branch from the first pipe 461 connecting the first ferrofluid source 451 to the first ferrofluid reservoir 421, and may be connected to the second ferrofluid reservoir 422. A first valve 471 may be provided as the ferrofluid flow control device 470 at a connection point between the first pipe 461 and the first branch pipe 463. The first valve 471 may selectively supply the first ferrofluid supplied from the first ferrofluid source 451 to the first pipe 461 and the first branch pipe 463. That is, the first valve 471 may allow the first ferrofluid supplied from the first ferrofluid source 451 to be supplied only to the first ferrofluid reservoir 421, to be supplied only to the second ferrofluid reservoir 422, or to be supplied both to the first ferrofluid reservoir 421 and to the second ferrofluid reservoir 422. The first valve 471 may be implemented as a group of multiple valves.

In addition, a second branch pipe 464 may branch from the second pipe 462 connecting the second ferrofluid source 452 to the second ferrofluid reservoir 422, and may be connected to the first ferrofluid reservoir 421. A second valve 472 may be provided as the ferrofluid flow control device 470 at a connection point between the second pipe 462 and the second branch pipe 464. The second valve 472 may selectively supply the second ferrofluid supplied from the second ferrofluid source 452 to the second pipe 462 and the second branch pipe 464. That is, the second valve 472 may allow the second ferrofluid supplied from the second ferrofluid source 452 to be supplied only to the second ferrofluid reservoir 422, to be supplied only to the first ferrofluid reservoir 421, or to be supplied both to the first ferrofluid reservoir 421 and to the second ferrofluid reservoir 422. The second valve 472 may be implemented as a group of multiple valves.

According to this configuration, it is possible to more finely control the magnetic field by selectively supplying different types of ferrofluids to the plurality of unit ferrofluid reservoirs 420. For example, as shown in FIG. 9B, the first ferrofluid may be supplied to the first ferrofluid reservoir 421, and the second ferrofluid may be supplied to the second ferrofluid reservoir 422. Conversely, as shown in FIG. 9C, the second ferrofluid may be supplied to the first ferrofluid reservoir 421, and the first ferrofluid may be supplied to the second ferrofluid reservoir 422. Alternatively, as shown in FIG. 9D, the second ferrofluid may be supplied both to the first ferrofluid reservoir 421 and to the second ferrofluid reservoir 422. Although not shown in the drawings, all the multiple valves constituting the first valve 471 may be opened, and all multiple valves constituting the second valve 472 may be closed, thereby supplying the first ferrofluid both to the first ferrofluid reservoir 421 and to the second ferrofluid reservoir 422.

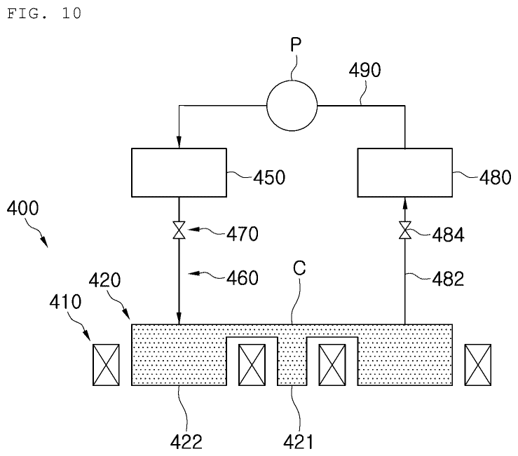

FIG. 10 is a view for explaining a ferrofluid discharge structure according to an embodiment of the present disclosure. In the embodiment shown in FIG. 10, a ferrofluid supply pipe and a ferrofluid recovery pipe are provided separately from each other.

Referring to FIG. 10, the ferrofluid is supplied from the ferrofluid source 450 to the ferrofluid reservoir 420 through the ferrofluid pipe 460. The substrate-processing process may be performed in the state in which the ferrofluid reservoir 420 is filled with the ferrofluid. When the substrate-processing process is completed, the ferrofluid is recovered from the ferrofluid reservoir 420 through a recovery pipe 482. A recovery valve 484 is provided on the recovery pipe 482.

The ferrofluid recovered through the recovery pipe 482 may return to the ferrofluid source 450. Alternatively, as shown in FIG. 10, the ferrofluid may be recovered to a ferrofluid tank 480 provided separately from the ferrofluid source 450. The ferrofluid recovered to the ferrofluid tank 480 may be transferred to the ferrofluid source 450 through a supplement pipe 490. A pump P may be provided on the supplement pipe 490 in order to provide driving force required for transfer of the ferrofluid.

According to this ferrofluid discharge structure, it is possible to always supply the ferrofluid in a homogenous state to the ferrofluid reservoir 420. That is, when the recovery pipe 482 is provided separately, the ferrofluid may be homogenized while circulating compared to when both the supply and the recovery of the ferrofluid are performed through the ferrofluid pipe 460.

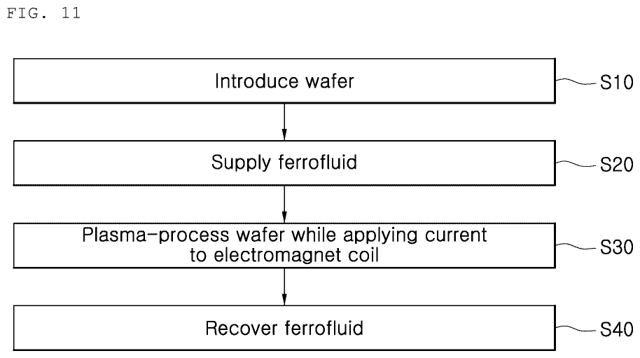

FIG. 11 is a flowchart of a substrate processing method according to an embodiment of the present disclosure.

Step S10 is a step of introducing a substrate W into the chamber 100. The substrate W introduced into the chamber 100 is placed on the substrate support unit 200.

Step S20 is a step of supplying ferrofluid. The controller 600 controls the ferrofluid source 450 to supply the ferrofluid to the ferrofluid reservoir 420 through the ferrofluid pipe 460.

Step S30 is a step of plasma-processing the substrate W while applying current to the coil of the electromagnet. The controller 600 controls the gas supply unit 300 and the plasma generation unit 500 to generate plasma in the processing space s. At this time, in order to precisely control the density distribution of the plasma, the controller 600 plasma-processes the substrate W while controlling the electromagnet unit 400. In detail, current is supplied to the coil module 410 to generate a magnetic field, and the density distribution of the plasma is controlled by the generated magnetic field. At this time, since the ferrofluid reservoir 420 is filled with the ferrofluid, a desired magnetic field may be generated while supplying relatively small current to the coil module 410. Accordingly, heat generation in the coil module 410 may be minimized.

When the substrate W is completely plasma-processed, step S40 of recovering the ferrofluid is performed. In the state in which the ferrofluid reservoir 420 is filled with the ferrofluid, the ferrofluid is magnetized as the magnetic powders are oriented along the magnetic field generated by the coil module 410. When the ferrofluid is recovered, the magnetic powders are randomly dispersed, and thus the ferrofluid is demagnetized. Accordingly, when the ferrofluid is again supplied to the ferrofluid reservoir 420 for subsequent substrate processing, the substrate-processing process may be performed under the same conditions as the previous substrate-processing process.

As is apparent from the above description, according to the embodiment of the present disclosure, since a ferrofluid reservoir, to which ferrofluid is supplied, is disposed between electromagnets, it is possible to form a magnetic field having a desired magnitude while suppressing heat generation in a coil.

In addition, according to the embodiment of the present disclosure, it is possible to precisely control a magnetic field through adequate arrangement of ferrofluid reservoirs and selective supply of ferrofluid to the ferrofluid reservoirs.

In addition, according to the embodiment of the present disclosure, since the ferrofluid is discharged from the ferrofluid reservoir after completion of a substrate-processing process, a demagnetization process is not necessary, and thus substrate processing efficiency may be improved.

Although the preferred embodiments of the present disclosure have been disclosed for illustrative purposes, those skilled in the art will appreciate that various modifications, additions and substitutions are possible, without departing from the scope and spirit of the disclosure.

The scope of the present disclosure should be defined only by the appended claims, and all technical ideas within the scope of equivalents to the claims should be construed as falling within the scope of the disclosure.

What is claimed is:

1. A substrate processing apparatus comprising:
a chamber having a processing space for processing of a substrate;
a substrate support unit disposed in the chamber;
a gas supply unit configured to supply gas to the processing space of the chamber;
a plasma generation unit comprising a high-frequency power supply configured to generate plasma in the processing space; and
an electromagnet unit configured to generate a magnetic field in the processing space,
wherein the electromagnet unit comprises:
a coil module; and
a ferrofluid reservoir disposed adjacent to the coil module.

2. The substrate processing apparatus as claimed in claim 1,
wherein the coil module comprises a plurality of unit coils, and
wherein the ferrofluid reservoir is disposed between the plurality of unit coils.

3. The substrate processing apparatus as claimed in claim 2,
wherein the ferrofluid reservoir comprises a plurality of unit ferrofluid reservoirs, and
wherein each of the plurality of unit ferrofluid reservoirs is formed in an annular shape or a cylindrical shape.

4. The substrate processing apparatus as claimed in claim 3,
wherein the plurality of unit coils comprises annular coils having different diameters and disposed concentrically with each other, and
wherein at least one of the plurality of unit ferrofluid reservoirs is disposed between every two adjacent ones of the plurality of unit coils.

5. The substrate processing apparatus as claimed in claim 1, further comprising:
a ferrofluid source; and
a ferrofluid pipe configured to supply ferrofluid from the ferrofluid source to the ferrofluid reservoir.

6. The substrate processing apparatus as claimed in claim 5,
wherein the ferrofluid reservoir comprises a plurality of unit ferrofluid reservoirs, and
wherein the ferrofluid source is configured to supply the ferrofluid to the plurality of unit ferrofluid reservoirs.

7. The substrate processing apparatus as claimed in claim 5,
wherein the ferrofluid reservoir comprises a plurality of unit ferrofluid reservoirs, and
wherein the ferrofluid source is provided in plural, and each of the plurality of ferrofluid sources is configured to supply the ferrofluid to at least one of the plurality of unit ferrofluid reservoirs.

8. The substrate processing apparatus as claimed in claim 7,
wherein the plurality of ferrofluid sources supplies different types of ferrofluids.

9. The substrate processing apparatus as claimed in claim 1,
wherein the ferrofluid reservoir comprises a plurality of unit ferrofluid reservoirs, and
wherein the plurality of unit ferrofluid reservoirs communicates with each other through a connection pipe.

10. The substrate processing apparatus as claimed in claim 1,
wherein the coil module comprises a first coil and a second coil, and
wherein a plurality of unit ferrofluid reservoirs is disposed between the first coil and the second coil.

11. The substrate processing apparatus as claimed in claim 10,
wherein the plurality of unit ferrofluid reservoirs is disposed so as to be stacked in a vertical direction.

12. The substrate processing apparatus as claimed in claim 10,
wherein the plurality of unit ferrofluid reservoirs is disposed so as to be separate from each other in a peripheral direction.

13. The substrate processing apparatus as claimed in claim 5, further comprising:
a recovery pipe configured to receive the ferrofluid recovered from the ferrofluid reservoir;
a ferrofluid tank configured to store the recovered ferrofluid; and
a supplement pipe configured to transfer the ferrofluid from the ferrofluid tank to the ferrofluid source.

14. A substrate processing apparatus comprising:
a chamber having a processing space for processing of a substrate;
a substrate support unit disposed in the chamber;
a gas supply unit configured to supply gas to the processing space of the chamber;
a plasma generation unit comprising a high-frequency power supply configured to generate plasma in the processing space; and
an electromagnet unit configured to generate a magnetic field in the processing space,
wherein the electromagnet unit comprises:
a coil module; and
a first ferrofluid reservoir and a second ferrofluid reservoir disposed adjacent to the coil module, and
wherein the substrate processing apparatus further comprises:
a first ferrofluid source configured to selectively supply ferrofluid to the first ferrofluid reservoir and the second ferrofluid reservoir;
a first pipe connecting the first ferrofluid source to the first ferrofluid reservoir;
a first branch pipe branching from the first pipe to be connected to the second ferrofluid reservoir; and
a first ferrofluid flow control device configured to control a ferrofluid supply path so that the ferrofluid is supplied to the first ferrofluid reservoir through the first pipe or is supplied to the second ferrofluid reservoir through the first branch pipe.

15. The substrate processing apparatus as claimed in claim 14, further comprising:
a second ferrofluid source configured to selectively supply the ferrofluid to the first ferrofluid reservoir and the second ferrofluid reservoir;
a second pipe connecting the second ferrofluid source to the second ferrofluid reservoir;
a second branch pipe branching from the second pipe to be connected to the first ferrofluid reservoir; and
a second ferrofluid flow control device configured to control the ferrofluid supply path so that the ferrofluid is supplied to the second ferrofluid reservoir through the second pipe or is supplied to the first ferrofluid reservoir through the second branch pipe.

16. The substrate processing apparatus as claimed in claim 15,
wherein the first ferrofluid source supplies first ferrofluid,
wherein the second ferrofluid source supplies second ferrofluid, and
wherein the first ferrofluid and the second ferrofluid are different types of ferrofluids.

17. The substrate processing apparatus as claimed in claim 16,
wherein one of the first ferrofluid and the second ferrofluid is supplied to the first ferrofluid reservoir and the second ferrofluid reservoir by the first ferrofluid flow control device and the second ferrofluid flow control device.

18. A substrate processing apparatus comprising:
a chamber having a processing space for processing of a substrate;
a substrate support unit disposed in the chamber;
a gas supply unit configured to supply gas to the processing space of the chamber;
a plasma generation unit comprising a high-frequency power supply configured to generate plasma in the processing space;
an electromagnet unit configured to generate a magnetic field in the processing space; and
a controller,
wherein the electromagnet unit comprises:
a coil module; and
a ferrofluid reservoir disposed adjacent to the coil module, and
wherein the controller controls:
a first process of introducing the substrate into the chamber and placing the substrate onto the substrate support unit;
a second process of supplying ferrofluid to the ferrofluid reservoir;
a third process of applying current to the coil module and controlling the plasma generation unit to generate plasma in the processing space so that the substrate is plasma-processed; and
a fourth process of recovering the ferrofluid from the ferrofluid reservoir when the substrate is completely plasma-processed.

19. The substrate processing apparatus as claimed in claim 18,
wherein the coil module comprises a plurality of unit coils, and
wherein the ferrofluid reservoir is disposed between the plurality of unit coils.

20. The substrate processing apparatus as claimed in claim 19,
wherein the plurality of unit coils comprises annular coils having different diameters and disposed concentrically with each other, and
wherein one or more unit ferrofluid reservoirs are disposed between every two adjacent ones of the plurality of unit coils.
